(19) United States
(12) Patent Application Publication
(10) Pub. No.: US 2009/0078945 A1
(43) Pub. Date: Mar. 26, 2009

(54) Light emitting device

(75) Inventor: Hongmo Koo, Gumi-city (KR)

Correspondence Address: KED & ASSOCIATES, LLP, P.O. Box 221200, Chantilly, VA, 20153-1200, US

(73) Assignee: LG Electronics Inc.

(21) Appl. No.: 11/987,751

(22) Filed: Dec. 4, 2007

(30) Foreign Application Priority Data
Sep. 21, 2007 (KR) 10-2007-0097018

(51) Int. Cl. H01L 33/00

(52) U.S. Cl. 257/89; 257/E33.061

(57) ABSTRACT

A light emitting device is provided that includes a substrate having a thin film transistor, and an insulation film disposed over the substrate and having a via hole to expose the thin film transistor. The light emitting device further includes a first electrode over the insulation film and connecting with the thin film transistor through the via hole, an emitting layer over the first electrode, a first function layer to cover the emitting layer, and a second electrode over the first function layer. A width of the first function layer is approximately 1.0 to 1.2 times a width of the emitting layer.

The present application claims priority from Korean Patent Application No. 10-2007-0097018, filed Sep. 21, 2007, the subject matter of which is incorporated herein by reference.

### BACKGROUND

1. Field

Embodiments of the present application may relate to a display. More particularly, embodiments of the present invention may relate to a light emitting device.

2. Background

The significance of Flat Panel Displays (FPDs) has been increasing with development of multimedia. Various displays such as Liquid Crystal Displays (LCDs), Plasma Display Panels (PDPs), Field Emission Displays (FEDs) and light emitting devices are being used.

Light emitting devices may have a high response speed (of 1 ms or less) and have a low consumption power. The light emitting devices may be self-emission structures that have a good viewing angle. The light emitting devices may be considered next generation display devices.

An Organic Light Emitting Diode (OLED) display device may include a substrate, a first electrode disposed over the substrate, an organic layer (or an inorganic layer) having an emitting layer and being disposed over the first electrode, and a second electrode disposed over the organic layer (or inorganic layer). The organic layer (or the inorganic layer) may have a Hole Injection Layer (HIL), a Hole Transfer layer (HTL), an Electron Transfer layer (ETL), and/or an Electron Injection Layer (EIL).

An operating principle of the light emitting device will now be briefly described. Holes may be injected into the emitting layer from the first electrode via the hole injection layer and the hole transfer layer when a voltage is applied between the first electrode and the second electrode. At the same time, electrons may be injected into the emitting layer from the second electrode via the electron injection layer and the electron transfer layer. Excitons may be generated by a recombination of holes and electrons injected into the emitting layer. Light emission may occur by energy generated during the transition of excitons to a ground state.

The emitting layer of the light emitting device is vulnerable to oxygen and moisture. Thus, the light emitting device may include a moisture absorption layer, etc. to protect the emitting layer.

### BRIEF DESCRIPTION OF THE DRAWINGS

Arrangements and embodiments may be described in detail with reference to the following drawings in which like reference numerals refer to like elements and wherein:

FIGS. 1A to 1C illustrate various implementations of a color image display method in a light emitting device

FIGS. 2 to 8 are cross sections illustrating a light emitting device according to example embodiments of the present invention; and

FIG. 9 is a cross section illustrating a light emitting device according to an example embodiment of the present invention.

### DETAILED DESCRIPTION

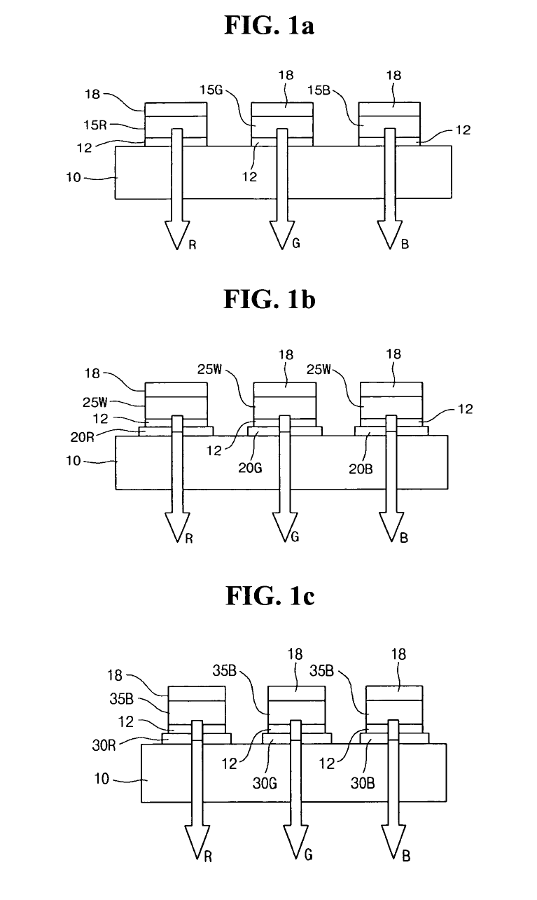

FIGS. 1A to 1C illustrate various implementations of a color image display method in a light emitting device. Other implementations may also be used. FIG. 1A illustrates a color image display method in an organic light emitting device that separately includes a red organic emitting layer 15R to emit red light, a green organic emitting layer 15G to emit green light and a blue organic emitting layer 15B to emit blue light. The red, green and blue light produced by the red, green and blue organic emitting layers 15R, 15G and 15B may be mixed to display a color image.

In FIG. 1A, the red, green and blue organic emitting layers 15R, 15G and 15B may each include an electron transfer layer, an emitting layer, a hole transfer layer, and the like. FIG. 1A also shows a substrate 10, an anode electrode 12 and a cathode electrode 18. Different dispositions and configurations of the substrate 10, the anode electrode 12 and the cathode electrode 18 may also be used.

FIG. 1B illustrates a color image display method in an organic light emitting device that includes a white organic emitting layer 25W to emit white light, a red color filter 20R, a green color filter 20G and a blue color filter 20B.

As shown in FIG. 1B, the red color filter 20R, the green color filter 20G and the blue color filter 20B each receive white light produced by the white organic emitting layer 25W and produce red light, green light and blue light, respectively. The red, green and blue light may be mixed to display a color image. And an organic light emitting device may further include a white color filter. So the organic light emitting device may realization various colors by manner of R/G/B or R/G/B/W

In FIG. 1B, the white organic emitting layer 25W may include an electron transfer layer, an emitting layer, a hole transfer layer, and the like.

FIG. 1C illustrates a color image display method in an organic light emitting device that includes a blue organic emitting layer 35B to emit blue light, a red color change medium 30R, a green color change medium 30G and a blue color change medium 30B.

As shown in FIG. 1C, the red color change medium 30R, the green color change medium 30G and the blue color change medium 30B each receive blue light produced by the blue organic emitting layer 35B and produce red light, green light and blue light, respectively. The red, green and blue light may be mixed to display a color image. In FIG. 1C, the blue organic emitting layer 35B may include an electron transfer layer, an emitting layer, a hole transfer layer, and the like.

Embodiments of the present invention may provide a light emitting device that protects an emitting layer from oxygen and moisture and provides enhanced luminous efficiency.

A light emitting device may include a substrate having a thin film transistor, and an insulation film disposed over the substrate and having a via hole to expose the thin film transistor. The light emitting device may further include a first electrode disposed over the insulation film and connected with the thin film transistor through the via hole, a pixel definition film on the substrate and the insulating film having an opening to expose the first electrode, an emitting layer disposed over the first electrode, a first function layer to cover the emitting layer, and a second electrode disposed over the first function layer. A width of the first function layer may be substantially more than a width of the emitting layer. As one example the width of the first function layer is greater than width X of the emitting layer, and is approximately 1.2 or less than the width of the emitting layer.

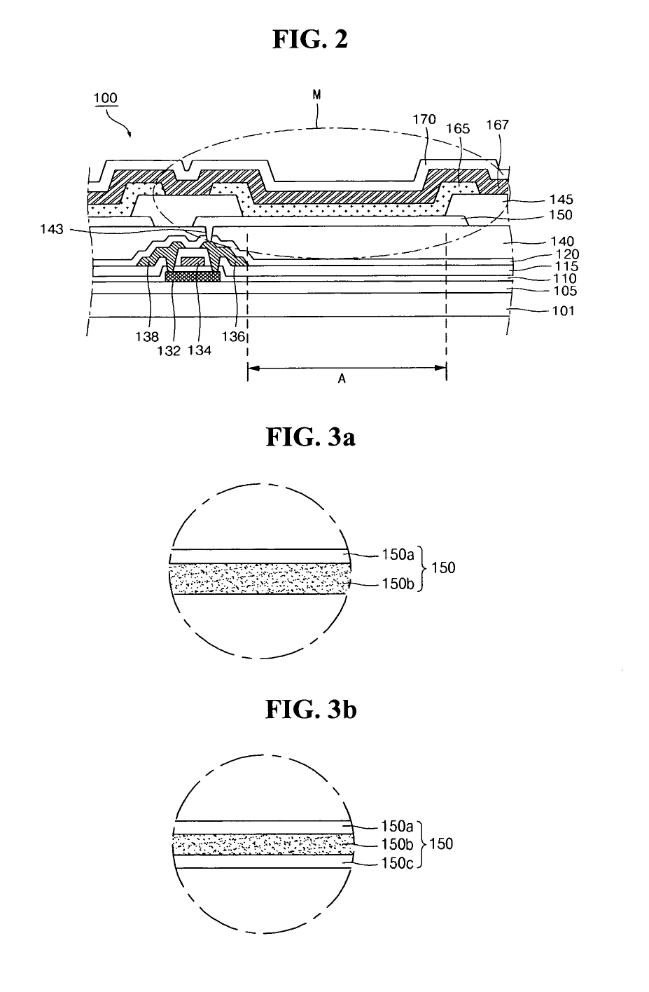

FIGS. 2 to 8 are cross sections illustrating a light emitting device according to example embodiments of the present invention. Other embodiments and configurations are also within the scope of the present invention.

FIGS. 2 and 3 show a light emitting device 100 that may include a substrate 101, a buffer layer 105, a thin film transistor, first to fifth insulation films 110, 115, 120, 140, and 145, a first electrode 150, an emitting layer 165, and a second electrode 170.

The substrate 101 may be made of transparent glass or plastic materials. The buffer layer 105 may be formed on the substrate 101 to prevent introduction of impurities generated from the substrate 101 into the device when the light emitting device 100 is being manufactured. The buffer layer 105 may include nitride silicon (SiNₓ), oxide silicon (SiO₂), or silicon oxide nitride (SiOₓNₓ), for example.

The thin film transistor may include a gate electrode 134, a source electrode 138, a drain electrode 136 and a semiconductor layer 132. The thin film transistor shown in FIG. 2 has a coplanar structure with a top gate where the gate electrode 134 is positioned on the semiconductor layer 132. Other configurations of a thin film transistor may also be used.

The semiconductor layer 132 may be formed on the buffer layer 105. The semiconductor layer 132 may form a channel in the thin film transistor. The semiconductor layer 132 may be made of crystalline, poly-crystalline, amorphous materials, etc. Other materials may also be used such as silicon (Si).

The first insulation film 110, which is a gate insulation film, may be formed on the buffer layer 105 on which the semiconductor layer 132 is formed. The first insulation film 110 may be made of oxide silicon or nitride silicon, for example. Embodiments are not limited to these materials. The first insulation film 110 may insulate the gate electrode 134, the source electrode 138 and the drain electrode 136.

The gate electrode 134 may be formed on the first insulation film 110 in a position corresponding to the semiconductor layer 132. The gate electrode 134 may turn the thin film transistor ON or OFF using a data voltage provided from a data line (not shown).

The second insulation film 115, which is an interlayer insulation film, may be formed on the first insulation film 110 on which the gate electrode 134 is formed. The second insulation film 115 may be made of oxide silicon or nitride silicon, for example. Embodiments are not limited to these materials.

A contact hole may be provided in the first insulation film 110 and the second insulation film 115 to form the drain electrode 136 and the source electrode 138 connecting with the semiconductor layer 132. The drain electrode 136 and the source electrode 138 may protrude and be formed on the second insulation film 115, connecting with the semiconductor layer 132 via the contact hole.

The gate electrode 134, the drain electrode 136 and the source electrode 138 may be formed in a laminated structure of one or more layers formed of chrome (Cr), aluminum (Al), molybdenum (Mo), argentums (Ag), copper (Cu), titanium (Ti), tantalum (Ta), and/or an alloy thereof.

The third insulation film 120, which is an inorganic protection film, may be formed on the thin film transistor and the second insulation film 115. The inorganic protection film may be formed to provide a passivation effect and an external light blocking effect for the semiconductor layer 132. The third insulation film 120 may be optionally provided.

The fourth insulation film 140, which is a planarization film, may be formed on the substrate 101 on which the third insulation film 120 is formed. The fourth insulation film 140 may be formed on the thin film transistor and the third insulation film 120 and have a via hole 143 to expose part of the thin film transistor (i.e., a part of the drain electrode 136). The fourth insulation film 140 may be made of any one selected from the group consisting of benzocyclobutene, polyimide, and/or acrylic-based resin, for example. Embodiments of the present invention are not limited to these materials.

The first electrode 150 may be formed on the fourth insulation film 140. The first electrode 150 may be electrically connected with the drain electrode 136 of the thin film transistor through the via hole 143 that is provided for the fourth insulation film 140 and the third insulation film 120.

The first electrode 150 may be an anode to provide holes to the emitting layer 165 by a voltage provided from the thin film transistor.

In a bottom-emission structure, the first electrode 150 may be configured with only a transparent electrode such as Indium Tin Oxide (ITO) or Indium Zinc Oxide (IZO). In addition, a thin film such as aluminum zinc oxide, tin oxide, magnesium indium oxide, nickel tungsten oxide, cadmium tin oxide, gallium nitride, indium nitride, gold, silver, aluminum, nickel, palladium, and/or platinum may also be used.

In a top-emission structure, the first electrode 150 may be bilayer that includes a reflection electrode 150b connecting with the thin film transistor through the via hole 143 and a first transparent electrode 150a formed on the reflection electrode 150b. The reflection electrode 150b may electrically connect with the drain electrode 136 of the thin film transistor and the first transparent electrode 150a may electrically connect with the reflection electrode 150b.

In the top-emission structure, the reflection electrode 150b may be positioned at a lower part of the first electrode 150 as shown in FIG. 3A. The reflection electrode 150b may reflect light generated from the emitting layer 165 toward the second electrode 170 when the emitting layer 165 emits light toward the first electrode 150 (rather than toward the second electrode 170). The reflection electrode 150b may be made with good reflectivity of any one of argentums (Ag), aluminum (Al), and/or titanium (Ti), for example. Embodiments of the present invention are not limited to these materials.

The first electrode 150 may be a triple layer as shown in FIG. 3B that includes a second transparent electrode 150c connecting with the drain electrode 136 of the thin film transistor through the via hole 143, the reflection electrode 150b formed on the second transparent electrode 150c, and the first transparent electrode 150a formed on the reflection electrode 150b.

Contact capability of connecting with the thin film transistor may increase for one embodiment when the first electrode 150 further includes the second transparent electrode 150c under the reflection electrode 150b as compared to another embodiment when the first electrode 150 includes the reflection electrode 150b and the first transparent electrode 150a (and without the second transparent electrode 150c). The first transparent electrode 150a and the second transparent electrode 150c may be made of any one of ITO and IZO. Also, the first transparent electrode 150a and the second transparent electrode 150c may use a thin film made of aluminum zinc oxide, tin oxide, magnesium indium oxide, nickel tungsten oxide, cadmium tin oxide, gallium nitride, indium nitride, gold, silver, aluminum, nickel, palladium, platinum, etc.

The fifth insulation film 145, which is a pixel definition film, may be formed on the fourth insulation film 140 and the first electrode 150. The fifth insulation film 145 may have an opening defining an emission region (A), exposing part of the first electrode 150. The fifth insulation film 145 may be made of any one selected from the group consisting of benzocyclobutene, polyimide, and/or acrylic-based resin, for example. Embodiments of the present invention are not limited to these materials.

The opening in the pixel definition film 145 may define an emission region (A) of the light emitting device 100 as shown in FIG. 2. The emission region (A) may represent one subpixel. Portions other than the emission region (A) may be non-emission regions.

The emitting layer 165 may be formed on the first electrode 150 to accept holes from the first electrode 150. The emitting layer 165 may be deposited on the first electrode 150 and part of the fifth insulation film 145 using a grill mask.

A first function layer 167 may be blanket deposited on the emitting layer 165 to cover up to a side surface of the emitting layer 165. The first function layer 167 may also be deposited through a mask to cover up to the side surface of the emitting layer 165. The first function layer 167 need not be blanket deposited as long as the first function layer 167 covers the side surface of the emitting layer 165. However, for process efficiency and structure, blanket deposition may be used to cover an entire exposed emitting layer 165.

The first function layer 167 may protect the emitting layer 165 from external oxygen and moisture by covering all of a top surface and all of a side surface of the emitting layer 165.

The first function layer 167 may include at least one of the electron transfer layer or the electron injection layer sequentially formed on the emitting layer 165.

The first function layer 167 includes at least one of the electron transfer layer and the electron injection layer. The electron transfer layer and the electron injection layer may be deposited separately or in common.

The electron injection layer (not shown) may be made of a fluorine (F)-based compound. The compound may be lithium fluoride (LiF), magnesium fluoride (MgF), etc., for example. Embodiments of the present invention are not limited to these materials. The electron injection layer formed of the above materials may have a great anti-corrosion effect.

LiF may have a strong ionic bond. The inter-element bond may be classified into a covalent bond and an ionic bond. This classification may be done with an absolute value of an electronegativity difference of each element. Elements may be ionic bonded when an absolute value of an electronegativity difference between bonded elements is 1.67 or more.

In LiF, an absolute value of an electronegativity difference between lithium (Li) and fluorine (F) may be 3 because lithium (Li) has an electronegativity of 3.98 and fluorine (F) has an electronegativity of 0.98. The result shows that LiF may have a very strong ionic bond. Of the ionic bond, a strong bond may form dipoles within the bond. In other words, LiF may have a strong ionic bond forming dipoles and have a very short inter-atom distance between the two elements.

LiF may form strong dipoles to provide enhanced electron injection into the emitting layer 160, to provide improved luminous efficiency, and to reduce a driving voltage.

Lithium complexes (Liq) may be weaker than LiF in bonding force, and may be used as materials for the electron injection layer to increase electron injection and enhance luminous efficiency.

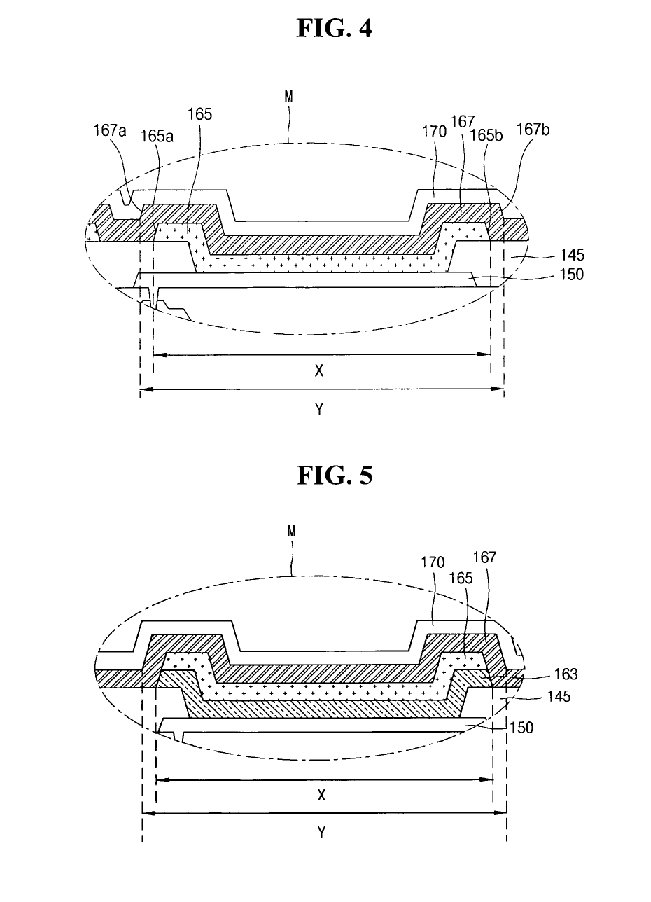

As shown in FIG. 4, a width Y of the first function layer 167 may be substantially more than a width X of the emitting layer 165. As one example, the width Y of the first function layer may be 1.2 times or less than the width X of the emitting layer 165.

As shown in FIG. 4, the width X of the emitting layer 165 is a distance (in one direction) from one end(165a) of the emitting layer 165 to another end(165b) of the emitting layer 165.

The width Y of the first function layer 167 is a distance in a direction between steps of the first function layer 167 formed on the pixel definition film (or fifth insulation film 145). The emitting layer 165 may be deposited on the first electrode 150 and part of the pixel definition film using a mask. When the first function layer 167 is formed on the emitting layer 165, the first function layer 167 may have steps at both ends of the emitting layer 165, as shown in FIG. 4. The steps may be formed based on the emitting layer 165 formed over the fifth insulation film 145 (or pixel definition film). In FIG. 4, these steps may be identified as a left step 167a and a right step 167b. The distance between an outside edge of the left step 167 and an outside edge of the right step 167b of the first function layer 167 may be defined as the width Y of the first function layer 167. The steps 167a and 167b may be raised surfaces compared to other surfaces of the first function layer 167. The width Y of the first function layer is greater than width X of the emitting layer, and is approximately 1.2 or less than the width X of the emitting layer.

The emitting layer 165 may be protected from external oxygen and moisture when the width Y of the first function layer 167 is more than the width X of the emitting layer 165. Additionally, a total size of the light emitting device 100 compared to the emission region A may not increase (or significantly increase) when the width Y of the first function layer 167 is 1.2 times or less than the width X of the emitting layer 165.

FIGS. 5 to 8 show various examples of an “M” portion (from FIG. 2). As shown in FIGS. 5 to 8, a second function layer 163 may be further provided between the first electrode 150 and the emitting layer 165. The second function layer 167 may include at least one of the hole injection layer and the hole transfer layer sequentially formed on the first electrode 150.

The first function layer 167 and the second function layer 163 may be blanket deposited or deposited through a mask.

The first function layer 167 may be formed to cover the emitting layer 165 or to cover the emitting layer 165 and the second function layer 163. The width Y of the first function layer 167 may be more than the width X of the emitting layer 165. For example, the width Y of the first function layer is greater than width X of the emitting layer, and is approximately 1.2 times or less than the width X of the emitting layer. As shown in FIG. 5, the second function layer 163 and the emitting layer 165 may be formed on the first electrode 150 at the emission region A and part of the fifth insulation film 145. The second function layer 163 and the emitting layer 165 may use a same mask and thereby reduce manufacturing cost. The first function layer 167 may be blanket deposited to cover the emitting layer 165 and the second function layer 163.

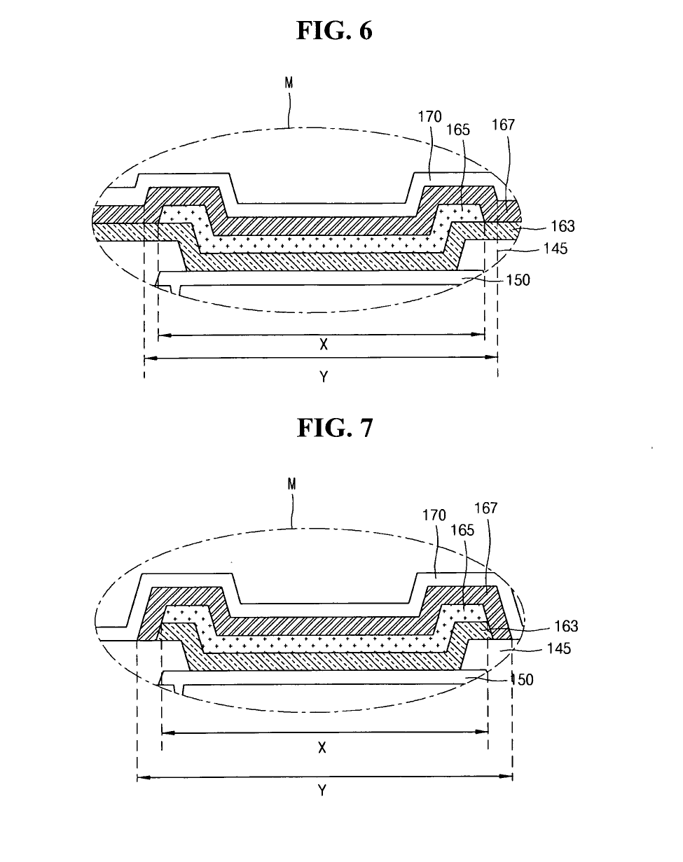

As shown in FIG. 6, the second function layer 163 may be blanket deposited on the first electrode 150 at the emission region A and the fifth insulation film 145 at the non-emission region. The emitting layer 165 may be formed on the second function layer 163 at the emission region A by using a mask. The first function layer 167 may be blanket deposited on the emitting layer 165 and the second function layer 163.

As shown in FIG. 7, the second function layer 163 and the emitting layer 165 may be positioned on the first electrode 150 at the emission region A and part of the fifth insulation film 145 by using a mask. The first function layer 167 may be patterned and formed to cover the emitting layer 165 and the second function layer 163.

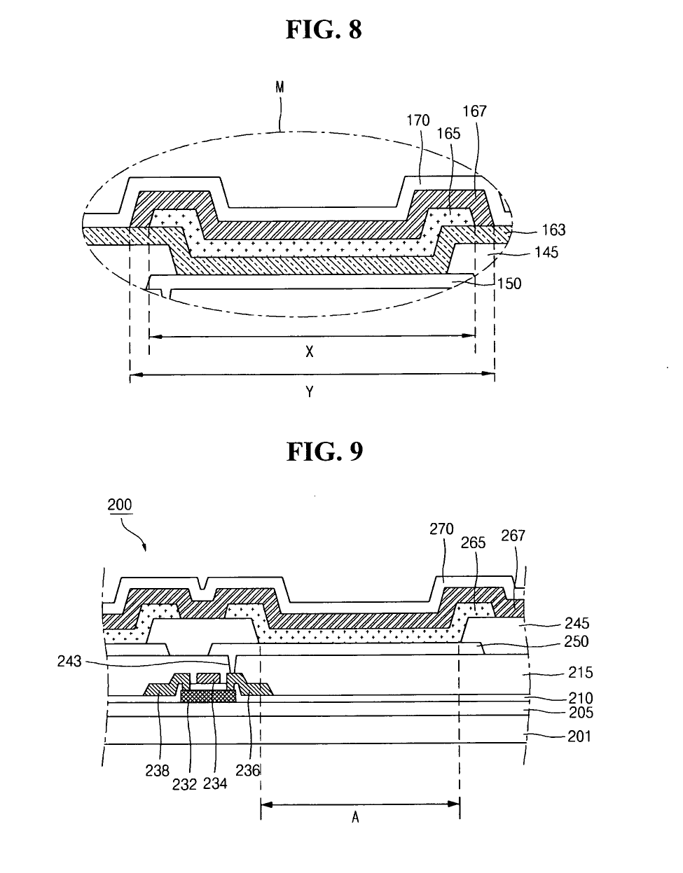

As shown in FIG. 8, the second function layer 163 may be blanket deposited over the first electrode 150 at the emission region A and the fifth insulation film 145 at the non-emission region. The emitting layer 165 may be positioned on the second function layer 163 at the emission region A. The first function layer 167 may be disposed over the emitting layer 165 and part of the fifth insulation film 145 at the non-emission region.

At least one of the emitting layer 165, the hole injection layer, the hole transfer layer, the electron transfer layer and the electron injection layer may be formed of organic or inorganic materials.

The hole injection layer or the electron injection layer formed of organic materials may further include inorganic materials. The organic materials may include a metal compound. The metal compound may include alkaline metal or alkaline earth metal. The metal compound including the alkaline metal or the alkaline earth metal may be any one selected from the group consisting of LiF, NaF, KF, RbF, CsF, FrF, BeF₂, MgF, CaF₂, SrF₂, BaF₂, and RaF₂, for example. Other material may also be used.

In the light emitting device 100, an amount of holes and electrons injected into the emitting layer 165 may be different because a mobility of holes may be about 10 or more times greater than a mobility of electrons. Thus, luminous efficiency of the light emitting device 100 may deteriorate.

Inorganic materials may lower a highest level of a valence band of the hole injection layer including only organic materials and a lowest level of a conduction band of the electron injection layer including only organic materials.

Thus, inorganic materials within the hole injection layer or the electron injection layer may improve luminous efficiency because balancing holes and electrons by decreasing a mobility of holes injected into the emitting layer 165 from the first electrode 150 or increasing a mobility of electrons injected into the emitting layer 165 from the second electrode 170.

The light emitting layer 165 may use fluorescent materials and/or phosphorescent materials. In consideration of an internal quantum efficiency of phosphorescent materials, a description will be made regarding the phosphorescent materials.

A red light emitting layer may include host materials having carbazole biphenyl (CBP) or mCP(1,3-bis(carbazol-9-yl). The red light emitting layer may be made of phosphorescent materials including dopants having at least any one selected from the group consisting of PIQIr(acac)(bis(1-phenylisoquinoline)acetylacetonate iridium), PQIr(acac)(bis(1-phenylquinoline)acetylacetonate iridium), PQIr(tris(1-phenylquinoline)iridium), and PtOEP(octaethylporphyrin platinum). Further materials include an iridium-based transition metal compound such as iridium(III)(2-(3-methylphenyl)-6-methylquinolinato-N,c2′)(2,4-penteindionate-O,O), platinum porphyrin class, etc. The red light emitting layer may also be made of PBD:Eu(DBM)3(Phen) or Perylene.

A blue light emitting layer may include host materials having CBP or mCP. The blue light emitting layer may be formed of phosphorescent materials including dopants having (4,6-F2ppy)2Irpic and/or an iridium-based transition metal compound such as (3,4-CN)3Ir, (3,4-CN)2Ir(picolinic acid), (3,4-CN)2Ir(N3), (3,4-CN)2Ir(N4), (2,4-CN)3Ir. The blue light emitting layer may be made of fluorescent materials including any one selected from the group consisting of spiro-DPVBi, spiro-6P, distylbenzene (DSB), distylaryllene (DSA), PFO-based polymer and/or PPV-based polymer, for example.

A green light emitting layer may include host materials having CBP or mCP. The green red light emitting layer may be made of phosphorescent materials including dopants having Ir(ppy)3(fac tris(2-phenylpyridine)iridium) and/or tris(2-phenypyridine)Ir(III), etc. The green light emitting layer may be made of fluorescent materials including Alq3(tris(8-hydroxyquinolino)aluminum).

FIG. 9 is a cross section illustrating a light emitting device according to an example embodiment of the present invention. Other embodiments and configurations are also within the scope of the present invention.

The light emitting device 200 may be the same or almost the same as the above-described light emitting device 100 other than the presence or absence of respective insulation films.

As shown in FIG. 9, the light emitting device 200 may not include a third insulation film 120 and a fourth insulation film 140 as shown in the light emitting device 100 of FIG. 2.

A thin film transistor may be of a planar structure in which a drain electrode 236, a gate electrode 234 and a source electrode 238 are disposed over a first insulation film 210 that may be designated as a gate insulation film.

A semiconductor layer 232 may be formed over a substrate 201 on which a buffer layer 205 is formed. The first insulation film 210 may be formed on the semiconductor layer 232. A gate electrode 234 may be formed on the first insulation film 210 corresponding to the semiconductor layer 232. The source electrode 238 and the drain electrode 236 may be formed on the first insulation film 210, connecting with the semiconductor layer 232 through a contact hole of the first insulation film 210.

A second insulation film 215, which is an interlayer insulation film, may be formed on the resulting substrate 201. The second insulation film 215 may be made of an organic film or an inorganic film and/or a complex film thereof. When the second insulation film 215 is the inorganic film, the second insulation film 215 may include silicon oxide (SiO₂), silicon nitride (SiNₓ), and/or Silicate On Glass (SOG). When the second insulation film 215 is the organic film, the second insulation film 215 may include acrylic-based resin, polyimide-based resin, and/or benzocyclobutene (BCB)-based resin.

A via hole 243 may be provided in the second insulation film 215 such that a first electrode 250 can connect with the drain electrode 236 of the thin film transistor through the via hole 243.

The light emitting unit 120, as discussed above, may include a plurality of unit pixels with each unit pixel including a plurality of subpixels. For example, FIGS. 1A-1C show different arrangements of red, blue, green and white light emitting layers to produce various combinations of red, blue and green light. Other combinations and/or colors may be used. The light emitting layers of the subpixels may include phosphorescence material and/or fluorescence material. The arrangements of FIGS. 1A-1C may be provided within any of the embodiments of the present invention and/or displays associated with each of FIGS. 2A-9.

In a case where the subpixel emits red light, the emitting layer of the subpixel may include a host material including carbazole biphenyl (CBP) or 1,3-bis(carbazol-9-yl (mCP), and may be formed of a phosphorescence material including a dopant material including PIQIr(acac)(bis(1-phenylisoquinoline)acetylacetonate iridium), PQIr(acac)(bis(1-phenylquinoline)acetylacetonate iridium), PQIr(tris(1-phenylquinoline)iridium), or PtOEP(octaethylporphyrin platinum) or a fluorescence material including PBD:Eu(DBM)3(Phen) or Perylene.

In the case where the subpixel emits green light, the emitting layer may include a host material including CBP or mCP, and may be formed of a phosphorescence material including a dopant material including Ir(ppy)3(fac tris(2-phenylpyridine)iridium) or a fluorescence material including Alq3(tris(8-hydroxyquinolino)aluminum).

In the case where the subpixel emits blue light, the emitting layer may includes a host material including CBP or mCP, and may be formed of a phosphorescence material including a dopant material including (4,6-F2ppy)2Irpic or a fluorescence material including spiro-DPVBi, spiro-6P, distyryl-benzene (DSB), distyryl-arylene (DSA), PFO-based polymers, PPV-based polymers, or a combination thereof.

And a difference between driving voltages, e.g., the power voltages VDD and Vss of the light emitting device may change depending on the size of the light emitting device 100(or 200) and a driving manner. A magnitude of the driving voltage is shown in the following Tables 1 and 2. Table 1 indicates a driving voltage magnitude in case of a digital driving manner, and Table 2 indicates a driving voltage magnitude in case of an analog driving manner.

TABLE 1

| | | | VDD-Vss |
|---|---|---|---|
| Size (S) of display panel | VDD-Vss (R) | VDD-Vss (G) | (B) |
| S < 3 inches | 3.5-10 (V) | 3.5-10 (V) | 3.5-12 (V) |
| 3 inches < S < 20 inches | 5-15 (V) | 5-15 (V) | 5-20 (V) |
| 20 inches < S | 5-20 (V) | 5-20 (V) | 5-25 (V) |

TABLE 2

| Size (S) of display panel | VDD-Vss (R, G, B) |
|---|---|
| S < 3 inches | 4~20 (V) |
| 3 inches < S < 20 inches | 5~25 (V) |
| 20 inches < S | 5~30 (V) |

Any reference in this specification to “one embodiment,” “an embodiment,” “example embodiment,” etc., means that a particular feature, structure, or characteristic described in connection with the embodiment is included in at least one embodiment of the invention. The appearances of such phrases in various places in the specification are not necessarily all referring to the same embodiment. Further, when a particular feature, structure, or characteristic is described in connection with any embodiment, it is submitted that it is within the purview of one skilled in the art to effect such feature, structure, or characteristic in connection with other ones of the embodiments.

Although embodiments have been described with reference to a number of illustrative embodiments thereof, it should be understood that numerous other modifications and embodiments can be devised by those skilled in the art that will fall within the spirit and scope of the principles of this disclosure. More particularly, various variations and modifications are possible in the component parts and/or arrangements of the subject combination arrangement within the scope of the disclosure, the drawings and the appended claims. In addition to variations and modifications in the component parts and/or arrangements, alternative uses will also be apparent to those skilled in the art.

What is claimed is:

1. A light emitting device comprising:
a substrate providing a thin film transistor;
an insulation film on the substrate;
a first electrode on the insulation film to couple with the thin film transistor;
a pixel definition film on the first electrode and the insulating film having an opening to expose the first electrode;
an emitting layer on the first electrode having a width X extending from a first end to a second end in a direction;
a first function layer on the emitting layer; and
a second electrode on the first function layer,
wherein a width Y of the first function layer extends in the direction from an outside edge of a first step of the first function layer to an outside edge of a second step of the first function layer,
wherein the width Y of the first function layer is greater than width X of the emitting layer, and is approximately 1.2 times or less than the width X of the emitting layer.

2. The device of claim 1, wherein the first electrode comprises an anode and the second electrode comprises a cathode.

3. The device of claim 1, wherein the first electrode includes a bilayer having a reflection electrode and a first transparent electrode or a triple layer having a second transparent electrode, a reflection electrode and a first transparent electrode.

4. The device of claim 3, wherein the reflection electrode is one of argentums (Ag), aluminum (Al) or nickel (Ni).

5. The device of claim 1, further comprising a second function layer provided between the first electrode and the emitting layer.

6. The device of claim 5, wherein the second function layer includes at least one of a hole injection layer and a hole transfer layer provided on the first electrode.

7. The device of claim 6, wherein at least one of the emitting layer, the hole injection layer and the hole transfer layer include organic materials or inorganic materials.

8. The device of claim 5, wherein at least one of the first function layer and the second function layer cover an emission region.

9. The device of claim 5, wherein at least one of the first function layer and the second function layer include an emission region and a non-emission region.

10. The device of claim 1, wherein the first function layer includes at least one of an electron transfer layer and an electron injection layer provided on the emitting layer.

11. The device of claim 10, wherein at least one of the electron transfer layer and the electron injection layer include organic materials or inorganic materials

12. The device of claim 7, wherein the hole injection layer including the organic materials further includes inorganic materials.

13. The device of claim 11, wherein the electron injection layer including the organic materials further includes inorganic materials.

14. The device of claim 1, wherein the insulation film comprises a planarization film or an interlayer insulation film.

15. The device of claim 10, wherein the electron injection layer comprises one of lithium fluoride (LiF) or lithium complexes (Liq).

16. A light emitting device comprising:
a substrate;
an insulation film on the substrate;
a first electrode on the insulation film to connect with a thin film transistor;
a pixel definition film on the first electrode and the insulating film, the pixel definition film having an opening to expose the first electrode;
an emitting layer provided on the first electrode and having a width X from a first end to a second end;
a first function layer to cover the emitting layer, the first function layer including at least one of an electron injection layer and an electron transfer layer; and
a second electrode on the first function layer,
wherein the first function layer includes a first step and a second step formed by the pixel definition film, and the first function layer has a width Y between an outside edge of the first step and an outside edge of the second step of the first function layer, and
wherein the width Y of the first function layer is greater than width X of the emitting layer, and is approximately 1.2 times or less than the width X of the emitting layer, and
wherein a lowest level of a conduction band of an electron injection layer comprising organic materials and inorganic materials is lower than a lowest level of a conduction band of an electron injection layer comprising only the organic materials.

17. The device of claim 16, further comprising a second function layer between the first electrode and the emitting layer, the second function layer including at least one of a hole injection layer and a hole transfer layer.

18. A light emitting device comprising:
a substrate;
an insulation film on the substrate;
a first electrode on the insulation film to connect with a thin film transistor;
a pixel definition film on the first electrode and the insulating film and having an opening exposing the first electrode;
an emitting layer on the first electrode and having a width X from a first end to a second end;
a first function layer to cover the emitting layer and having at least one of an electron injection layer and an electron transfer layer;
a second electrode on the first function layer; and
a second function layer between the emitting layer and the first electrode and having at least one of a hole injection layer and a hole transfer layer,
wherein a width Y of the first function layer extends from an outside edge of a first step of the first function layer to an outside edge of a second step of the first function layer, and
wherein the width Y of the first function layer is greater than width X of the emitting layer, and is approximately 1.2 times or less than the width X of the emitting layer, and
wherein a highest level of a valence band of a hole injection layer including organic materials and inorganic materials is lower than a highest level of a valence band of a hole injection layer including only the organic materials.

19. A light emitting device comprising:
a substrate to provide a plurality of pixels, each pixel including a plurality of subpixels;
an insulation film on the substrate;
a first electrode on the insulation film;
a pixel definition film on the first electrode and the insulating film and having an opening to expose the first electrode;
an emitting layer on the first electrode having a width X that extends from one end to another end;
a first function layer to cover the emitting layer; and
a second electrode on the first function layer,
wherein a width Y of the first function layer extends from an outside edge of a first step of the first function layer to an outside edge of a second step of the first function layer, and
wherein the width Y of the first function layer is greater than width X of the emitting layer, and is approximately 1.2 times or less than the width X of the emitting layer, and
wherein the plurality of subpixels for one of the pixels include fluorescent materials or phosphorescent materials.

20. The light emitting device of claim 19, wherein at least two of the subpixels of the one pixel include the fluorescent materials.

21. The light emitting device of claim 19, wherein at least two of the subpixels of the one pixel include the phosphorescent materials.

22. The light emitting device of claim 19, further comprising a second function layer between the first electrode and the emitting layer, the second function layer including at least one of a hole injection layer and a hole transfer layer.

23. The light emitting device of claim 19, wherein the first function layer includes at least one of an electron transfer layer and an electron injection layer provided on the emitting layer.
